(19) United States
(12) Patent Application Publication
(10) Pub. No.: US 2026/0299045 A1
(43) Pub. Date: Oct. 1, 2026

(54) METHOD AND APPARATUS FOR IDENTIFYING AN ABNORMAL BATTERY CELL

(71) Applicant: SAMSUNG SDI CO., LTD., Yongin-si (KR)

(72) Inventor: KYOSONG KOO, Yongin-si (KR)

(21) Appl. No.: 19/412,436

(22) Filed: Dec. 8, 2025

(30) Foreign Application Priority Data
Mar. 26, 2025 (KR) 10-2025-0038682

(51) Int. Cl. G01R 31/396; G01R 31/367; G01R 31/371; G01R 31/392

(52) U.S. Cl. CPC G01R 31/396; G01R 31/367; G01R 31/371; G01R 31/392

(57) ABSTRACT

Provided is a method and apparatus for identifying an abnormal battery cell. An apparatus for identifying an abnormal battery cell includes a memory in which at least one program is stored, and at least one processor configured to execute the at least one program. The at least one processor is further configured to perform a balancing operation based on a voltage difference between a plurality of battery cells, measure a time spent to perform the balancing operation and accumulate the times for respective ones of the battery cells, and identify at least one abnormal battery cell satisfying an abnormality determination criterion among the plurality of battery cells based on the accumulated times.

### CROSS-REFERENCE TO RELATED APPLICATION

This application is based on and claims priority under 35 U.S.C. § 119 to Korean Patent Application No. 10-2025-0038682, filed on Mar. 26, 2025, in the Korean Intellectual Property Office, the disclosure of which is incorporated by reference herein in its entirety.

### BACKGROUND

### 1. Field

The present disclosure relates to a method and apparatus for identifying an abnormal battery cell.

### 2. Description of the Related Art

Unlike primary batteries that cannot be recharged after being discharged, secondary batteries are batteries that can be discharged and recharged. Low-capacity secondary batteries are used in small portable electronic devices such as smartphones, feature phones, laptop computers, digital cameras, and camcorders, and high-capacity secondary batteries are used as driving power sources and power storage batteries for motors in hybrid vehicles, electric vehicles, and the like. Such a secondary battery includes an electrode assembly including a positive electrode and a negative electrode, a case for accommodating the electrode assembly, and an electrode terminal connected to the electrode assembly.

The capacity of a secondary battery may change as the secondary battery is used, and thus a balancing operation of cells included in the secondary battery may be desired. The balancing operation may be repeated unnecessarily, however, when an abnormal cell is present, which may cause a safety problem in a secondary battery.

The above information disclosed in this section of BACKGROUND ART is only for enhancement of understanding of the background of the present disclosure and therefore it may contain information that does not form a related art.

### SUMMARY

One or more embodiments of the present disclosure is directed to providing a method and apparatus for identifying an abnormal battery cell. One or more embodiments of the present disclosure is also directed to providing a computer-readable recording medium having recorded thereon a program for causing the method to be executed on a computer.

However, the technical objects to be solved by the present disclosure are not limited to the above, and other objects that are not described herein will be clearly understood by those skilled in the art from the following portion descriptions of the present disclosure.

According to an embodiment of the present disclosure, a method for identifying an abnormal battery cell includes performing a balancing operation based on a voltage difference between a plurality of battery cells, measuring times spent to perform the balancing operation and accumulating the times for respective ones of the battery cells, and identifying at least one abnormal battery cell satisfying an abnormality determination criterion among the plurality of battery cells based on the accumulated times.

According to an embodiment of the present disclosure, an apparatus for identifying an abnormal battery cell includes a processor and a memory. The memory stores instructions that, when executed by the processor, cause the processor to perform a balancing operation based on a voltage difference between a plurality of battery cells, measure times spent to perform the balancing operation and accumulate the times for respective ones of the battery cells for generating an accumulated time for the respective ones of the battery cells, and identify at least one abnormal battery cell satisfying an abnormality determination criterion among the plurality of battery cells based on the accumulated times.

A computer-readable recording medium according to some embodiments of the present disclosure includes a computer-readable recording medium having recorded thereon a program for causing the method to be executed on a computer.

### BRIEF DESCRIPTION OF THE DRAWINGS

The accompanying drawings illustrate exemplary embodiments of the present disclosure and, together with the following portion detailed description, serve to provide further understanding of the technical spirit of the present disclosure. However, the present disclosure is not to be construed as being limited to the details shown in the drawings, in which:

FIG. 1 depicts a schematic block diagram of a battery pack for which an abnormal battery cell may be identified according to an embodiment;

FIG. 2 depicts a block diagram of an apparatus for identifying an abnormal battery cell according to an embodiment;

FIG. 3 depicts a flowchart of a method for identifying an abnormal battery cell according to an embodiment;

FIG. 4 depicts a schematic block diagram of a battery pack for which a balancing operation is to be performed according to an embodiment;

FIG. 5 depicts a flowchart for a method for calculating an abnormality determination criterion according to an embodiment; and

FIG. 6 depicts a conceptual diagram of a method for identifying an abnormal battery cell according to an embodiment.

### DETAILED DESCRIPTION

Hereinafter, embodiments of the present disclosure will be described with reference to the accompanying drawings. Prior to the description, it should be understood that the terms used in the specification and the appended claims should not be construed as limited to general and dictionary meanings, but interpreted based on the meanings and concepts corresponding to technical aspects of the present disclosure on the basis of the principle that the inventor can be his/her own lexicographer to appropriately define terms to describe his/her invention in the best way. Accordingly, embodiments disclosed in the present specification and configurations illustrated in the drawings are merely exemplary embodiments of the present disclosure and do not represent all of the technical ideas of the present disclosure, and thus it should be understood that there may be various equivalents and modifications that can substitute these embodiments at the time of filing of the present application.

Further, “comprise and include” and/or “comprising and including” used in this specification should be interpreted as specifying the presence of described shapes, numbers, steps, operations, members, elements, and/or groups thereof and do not exclude the presence or addition of other shapes, numbers, operations, members, elements, and/or groups thereof. Further, the use of “may” and “may be” when describing embodiments of the present disclosure refers to “one or more embodiments of the present disclosure.”

In addition, for a better understanding of the present disclosure, the accompanying drawings are not illustrated on an actual scale and sizes of some elements may be exaggerated. In addition, the same reference numbers may be assigned to the same components in different embodiments.

Stating that two objects of comparison are “the same” means that the two objects of comparison are “substantially the same.” Therefore, substantially the same may include a deviation that is considered low in the art, for example, a deviation of 5% or less. In addition, uniformity of a parameter in a certain area may mean uniformity from an average perspective.

It will be understood that, although the terms first, second, and the like are used herein to describe various components, these components should not be limited by these terms. These terms are only used to distinguish one component from another component, and a first component may also be a second component unless particularly described otherwise.

Through the specification, each component may be singular or plural unless particularly described otherwise.

When it is said that an arbitrary element is disposed on “an upper portion (or a lower portion)” of an element or disposed “above (or below)” an element, this may not only mean that the arbitrary element is disposed in contact with an upper surface (or a lower surface) of the element, but also mean that another element may be interposed between the element and the arbitrary element disposed above (or below) the element.

Also, when it is said that a certain element is “connected” or “coupled” to another element, this may mean that the elements are directly connected or coupled to each other, but it should be understood that another element may be “interposed” between the elements or the elements may be “connected” or “coupled” to each other via another element. Further, the term “electrically coupled” may mean not only “directly coupled” but also may include “coupled via other interposing component.”

Throughout the specification, “A and/or B” refers to “A, B, or A and B” unless particularly described otherwise. That is, “and/or” includes all or any combination of a plurality of listed items. “C to D” refers to C or more and D or less unless particularly described otherwise.

The terms used in this specification are for describing embodiments of the present disclosure and are not intended to limit the present disclosure.

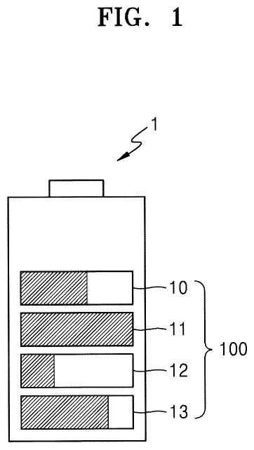

The present disclosure will be described in detail with reference to the accompanying drawings. Specifically, a method of identifying an abnormal battery cell according to an embodiment will be described in more detail with reference to FIGS. 1 to 6. However, the embodiments may be implemented in various forms and are not limited to the examples described herein.

FIG. 1 depicts a schematic block diagram of a battery pack for which an abnormal battery cell may be identified according to an embodiment.

Hereinafter, an example of the method of identifying an abnormal battery cell will be briefly described with reference to FIG. 1.

Referring to FIG. 1, a battery pack 1 may include one or more battery cells 100. For example, the one or more of battery cells 100 may include a first battery cell 10, a second battery cell 11, a third battery cell 12, and an m^{th} battery cell 13 (where “m” is a natural number that is greater than or equal to 4). In some embodiments, the first battery cell 10, the second battery cell 11, the third battery cell 12, and the m^{th} battery cell 13 may have different charging or discharging environments, cell characteristics, and the like.

In some embodiments, a balancing operation may be performed based on a voltage of the one or more of battery cells 100. In some embodiments, the balancing operation may include a process of substantially uniformly maintaining a voltage or a state of charge between the one or more of battery cells 100 in the battery pack 1.

For example, by using a time taken to perform a balancing operation on one or more (e.g., each) of the first battery cell 10, the second battery cell 11, the third battery cell 12, and the m^{th} battery cell 13, a battery cell satisfying an abnormality criterion, referred to herein as a battery cell with an abnormality or an abnormal battery cell, among the one or more of battery cells 100, may be identified.

In some embodiments, a battery cell with an abnormality may be detected to provide a notification to a user for providing user safety. In some embodiments, charging of the battery may limited, or used of the battery stopped based on the detecting the battery cell with an abnormality.

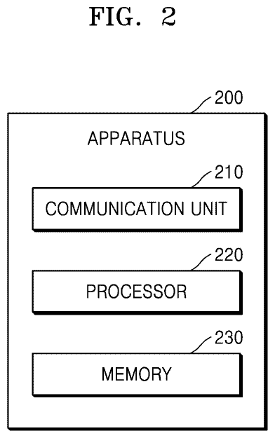

FIG. 2 depicts a block diagram of an apparatus 200 for identifying an abnormal battery cell according to an embodiment.

Referring to FIG. 2, the apparatus 200 for identifying an abnormal battery cell (hereinafter referred to as apparatus) may include a communication unit 210, a processor 220, and a memory 230. In the apparatus 200 of FIG. 2, only components related to the embodiment are shown. Accordingly, it will be appreciated by a person of ordinary skill in the art that other components may be included in addition to the components shown in FIG. 2.

The communication unit 210 may include one or more components that enable wired/wireless communication with an external server or external device. For example, the communication unit 210 may include a short-range communication unit (not shown) for communication with an external server or external device, and/or a mobile communication unit (not shown).

The memory 230 may be hardware that stores various types of data processed by the apparatus 200 and may store a program or computer instructions for processing and control of the processor 220. For example, the memory 230 may store various types of data such as data related to charging and discharging of a battery, a time taken or spent to perform a balancing operation on one or more battery cells, an average value of the times taken or spent to perform the balancing operation on the one or more battery cells, a standard deviation value, and data generated according to the operation of the processor 220. In some embodiments, the memory 230 may store an operating system (OS) and at least one program (for example, a program for operating the processor 220).

The memory 230 may include a random access memory (RAM) such as a dynamic random access memory (DRAM) or a static random access memory (SRAM), a read-only memory (ROM), an electrically erasable programmable read-only memory (EEPROM), a compact disk (CD)-ROM, a Blu-ray or other optical disk storage, a hard disk drive (HDD), a solid state drive (SSD), and/or a flash memory.

The processor 220 may be configured to control the overall operation of the apparatus 200. For example, the processor 220 may control the overall operation of an input unit (not shown), a display (not shown), the communication unit 210, the memory 230, or the like by executing one or more programs stored in the memory 230.

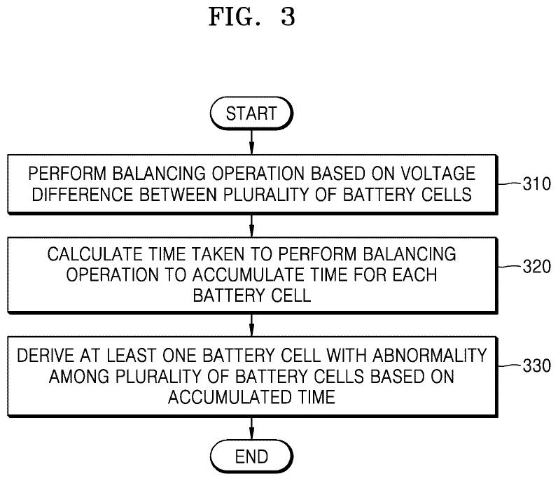

The processor 220 may be implemented by using at least one of application specific integrated circuits (ASICs), digital signal processors (DSPs), digital signal processing devices (DSPDs), programmable logic devices (PLDs), field programmable gate arrays (FPGAs), controllers, microcontroller units, microprocessors, and other electrical units for performing functions. The processor 220 may control the operation of the apparatus 200 by executing the one or more programs stored in the memory 230. As an example, the processor 220 may perform at least some of the methods for identifying an abnormal battery cell described with reference to FIGS. 3 to 6.

FIG. 3 depicts a flowchart of a method for identifying an abnormal battery cell according to an embodiment. The method may be performed, for example, by the processor 220.

Referring to FIG. 3, the method for identifying an abnormal battery cell may include operations 310 to 330. However, one or more embodiments are not limited thereto, and other operations may be included in the method for identifying an abnormal battery cell in addition to the operations shown in FIG. 3. In some embodiments, as described above with reference to FIGS. 1 and 2, at least one of the operations of the flowchart shown in FIG. 3 is executed by the processor 220.

In operation 310, the processor 220 may perform a balancing operation based on a voltage difference between a plurality of battery cells. For example, the processor 220 may perform the balancing operation based on determining that the voltage difference between the plurality of battery cells is greater than or equal to a preset value. For example, the processor 220 may identify a battery cell on which the balancing operation is to be performed (hereinafter referred to as a “balancing battery cell”) among the plurality of battery cells based on determining that the voltage difference is greater than or equal to the preset value, and may perform the balancing operation on the identified balancing battery cell. The balancing operation may include, for example, redistributing energy between the cells by bleeding-off excess energy from higher-charged cells or transferring energy to lower-charged cells.

In operation 320, the processor 220 may measure a time taken to perform the balancing operation and may accumulate the measured time for the one or more battery cells for which the balancing operation was performed. For example, the processor 220 may measure and individually accumulate a times taken to perform the balancing operation on each of the one or more of battery cells. In this regard, the processor 220 may measure individual times spent by each of the one or more battery cells to perform the balancing operation, and add the individual times to generate the accumulated time.

In operation 330, the processor 220 may identify at least one battery cell with an abnormality among the one or more of battery cells based on the accumulated time. For example, the processor 220 may use the accumulated time to calculate an abnormality determination criterion (or abnormality criterion) for the one or more of battery cells and may identify at least one abnormal battery cell among the one or more of battery cells that satisfies the abnormality determination criterion for the one or more of battery cells.

In some embodiments, the abnormality determination criterion may include at least one upper limit criterion (upper threshold) or at least one lower limit criterion (lower threshold). The upper limit criterion may be used to identify a battery cell for which an accumulated time exceeds the upper limit criterion, as an abnormal battery cell. The lower limit criterion may be used to identify a battery cell for which an accumulated time is below the lower limit criterion, as an abnormal battery cell. For example, the processor 220 may use the total sum of time accumulated for one or more (e.g., each) battery cell to calculate an overall average value of accumulated times for respective battery cells, and may use the calculated overall average value to calculate the abnormality determination criterion. In some embodiments, the calculated overall average value may be the upper threshold and/or the lower threshold.

In some embodiments, the processor 220 may determine whether an accumulated time of one battery cell of the one or more of battery cells satisfies the abnormality determination criterion and may determine the one battery cell as an abnormal battery cell based on determining that the accumulated time of the one battery cell satisfies the abnormality determination criterion.

As an additional example, the processor 220 may provide a notification based on a result of identifying an abnormal battery cell. For example, the processor 220 may provide one of a simple notification, a battery charge limit command, and a battery use stop command based on the result of identifying the abnormal battery cell. Based on receipt of the notification, battery charging and/or battery use may be stopped,

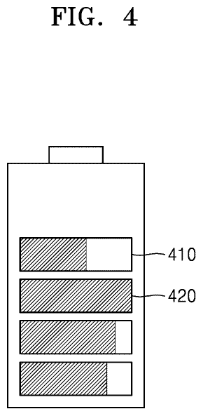

FIG. 4 depicts a schematic block diagram of a battery pack for which a balancing operation is to be performed according to an embodiment.

Hereinafter, an example of a method by which the processor 220 identifies a battery cell on which a balancing operation is to be performed among a one or more of battery cells 410 and 420 will be described with reference to FIG. 4.

Referring to FIG. 4, the processor 220 may identify or determine the battery cell on which the balancing operation is to be performed among the one or more of battery cells 410 and 420. For example, the processor 220 may perform the balancing operation based on determining that a voltage difference between the one or more of battery cells 410 and 420 is greater than or equal to a preset value. For convenience of description, the one or more of battery cells 410 and 420 are shown in FIG. 4 as including only two battery cells, but it should be apparent to a person of ordinary skill in the art that the embodiments are not limited thereto, and that the battery pack may include more than two battery cells.

For example, the processor 220 may measure a voltage of each of the plurality of battery cells 410 and 420 and may calculate the voltage difference between the plurality of battery cells 410 and 420. In some embodiments, the processor 220 may determine whether the calculated voltage difference is greater than or equal to the preset value. In some embodiments, the preset value may be 100 mV, but is not limited thereto. The preset value may be set depending on a state of the battery cell, a surrounding environment of the battery cell, or the like.

In some embodiments, the processor 220 may perform the balancing operation based on the voltage difference between the plurality of battery cells 410 and 420. More specifically, the processor 220 may perform the balancing operation based on determining that the voltage difference between the plurality of battery cells 410 and 420 is greater than or equal to the preset value. For example, the processor 220 may identify a first battery cell among the plurality of battery cells 410 and 420 that has a voltage difference with a second battery cell of the plurality of battery cells 410 and 420 that is greater than or equal to the preset value.

Based on the processor 220 determining that the voltage difference between the plurality of battery cells 410 and 420 (e.g., the first and second battery cells) is greater than or equal to the preset value, the processor 220 may perform the balancing operation on the plurality of battery cells 410 and 420 (e.g., the first and second battery cells) including the first battery cell (e.g., battery cell 410) with a low voltage. In this regard, the processor 220 may identify the first battery cell 410 with a low voltage among the plurality of battery cells 410 and 420 as the balancing battery cell.

According to another example, based on the processor 220 determining that the voltage difference between the plurality of battery cells 410 and 420 (e.g., the first and second battery cells) is greater than or equal to the preset value, the processor 220 may perform the balancing operation on the plurality of battery cells 410 and 420 (e.g., the first and second battery cells) including the second battery cell (e.g., battery cell 420) with a high voltage. In this regard, the processor 220 may identify the second battery cell 420 with a high voltage among the plurality of battery cells 410 and 420 as the balancing battery cell. In this manner, the processor 220 may perform the balancing operation on the identified balancing battery cell.

In some embodiments, the processor 220 may accumulate a time taken to perform the balancing operation for one or more (e.g., each) battery cell. For example, the processor 220 may measure and individually accumulate a time taken to perform the balancing operation on each of the plurality of battery cells 410 and 420. In some embodiments, the balancing operation may be performed on all of a plurality of battery cells rather than just one specific battery cell so that the processor 220 may measure a time taken to perform the balancing operation on each battery cell and may accumulate and store the measured time for each battery cell. For example, the processor 220 may measure a first time spent to perform the balancing operation on battery cell 410, and measure a second time spent to perform the balancing operation on battery cell 420. The processor may add the first time and the second time to generate the accumulated time.

In some embodiments, the processor 220 may identify at least one battery cell with an abnormality among the plurality of battery cells 410 and 420 based on the accumulated time. The processor 220 may use the accumulated time to calculate an abnormality determination criterion for the plurality of battery cells 410 and 420.

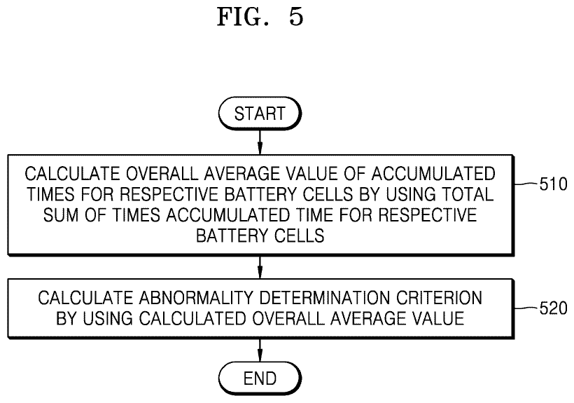

FIG. 5 depicts a flowchart for of a method for calculating an abnormality determination criterion according to an embodiment. The method may be performed, for example, by the processor 220.

Referring to FIG. 5, in operation 510, the processor 220 may calculate an overall average value of accumulated times for the respective battery cells based on a total sum of times accumulated for the respective battery cells. For example, the processor 220 may calculate the total amount of time taken to perform a balancing operation on one or more (e.g., all) battery cells, and may use the calculated total amount of time to calculate the overall average value of the times taken to perform the balancing operation on the one or more (e.g., all) battery cells.

In operation 520, the processor 220 may calculate the abnormality determination criterion by using the calculated overall average value. For example, the abnormality determination criterion may include at least one upper limit criterion or at least one lower limit criterion. The upper limit criterion may refer to a criterion for identifying a battery cell for which an accumulated time exceeds the upper limit criterion, as an abnormal battery cell. The lower limit criterion may refer to a criterion for identifying a battery cell for which an accumulated time falls below the lower limit criterion, as an abnormal battery cell.

For example, when an accumulated time taken to perform a balancing operation on a battery cell exceeds the upper limit criterion, the processor 220 may determine the battery cell as an abnormal battery cell. In some embodiments, when an accumulated time taken to perform a balancing operation on a battery cell falls below the lower limit criterion, the processor 220 may determine the battery cell as an abnormal battery cell.

For example, the processor 220 may use the calculated overall average value to calculate a standard deviation value of the times taken to perform the balancing operation on the one or more of battery cells. In some embodiments, the processor 220 may use the calculated standard deviation value to determine the abnormality determination criterion.

For example, the processor 220 may determine the abnormality determination criterion by using the overall average value and a k standard deviation value (where k is a natural number that is greater than or equal to 1). As an example, the processor 220 may determine a value, which is obtained by adding the overall average value and the k standard deviation value, as the abnormality determination criterion, more specifically, the upper limit criterion. As another example, the processor 220 may determine a value, which is obtained by subtracting the k standard deviation value from the overall average value, as the abnormality determination criterion, more specifically, the lower limit criterion.

In some embodiments, the number of abnormality determination criteria is not limited, and the upper limit criterion and the lower limit criterion may include a plurality of upper limit criteria and a plurality of lower limit criteria, respectively. For example, the processor 220 may identify at least one abnormal battery cell among the one or more of battery cells based on the abnormality determination criterion.

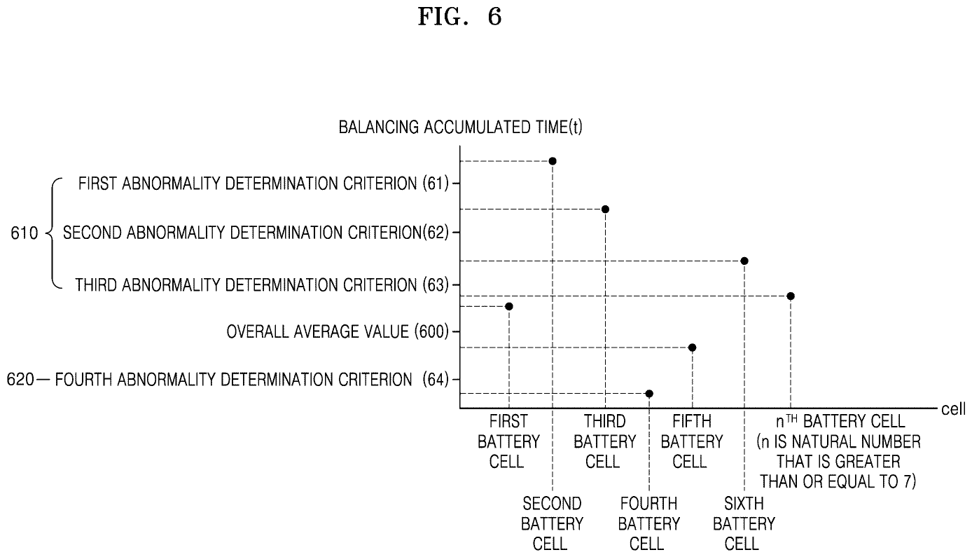

FIG. 6 depicts a conceptual diagram of a method for identifying an abnormal battery cell according to an embodiment. The method may be performed, for example, by the processor 220.

Referring to FIG. 6, the processor 220 may determine whether an accumulated time taken or spent to perform a balancing operation on each (e.g., one or more) battery cell satisfies an abnormality determination criterion. For example, the processor 220 may determine whether an accumulated time of one battery cell among a plurality of battery cells satisfies the abnormality determination criterion.

In some embodiments, the abnormality determination criterion may include a first abnormality determination criterion 61, a second abnormality determination criterion 62, a third abnormality determination criterion 63, and a fourth abnormality determination criterion 64. In some embodiments, the first abnormality determination criterion 61, the second abnormality determination criterion 62, the third abnormality determination criterion 63 may each be an upper limit criterion 610, and the fourth abnormality determination criterion 64 may be a lower limit criterion 620.

In some embodiments, the processor 220 may determine the first abnormality determination criterion 61 as a value obtained by adding an overall average value and an 8-standard deviation value. The processor 220 may determine the second abnormality determination criterion 62 as a value obtained by adding an overall average value and a 5-standard deviation value. The processor 220 may determine the third abnormality determination criterion 63 as a value obtained by adding an overall average value and a 2-standard deviation value. The processor 220 may determine the fourth abnormality determination criterion 64 as a value obtained by subtracting a 5-standard deviation value from an overall average value. The abnormality determination criteria of FIG. 6 are merely examples, and one or more embodiments are not limited thereto.

In some embodiments, when an accumulated time of a battery cell deviates from an overall average value 600 by a certain range or more and satisfies the upper limit criterion 610 or the lower limit criterion 620, the processor 220 may determine the corresponding battery cell as an abnormal battery cell. In some embodiments, the certain range may refer to the upper limit criterion 610 closest to the overall average value 600 and the lower limit criterion 620 closest to the overall average value, and in FIG. 6, the certain range may refer to a range between the third abnormality determination criterion 63 and the fourth abnormality determination criterion 64.

For example, the processor 220 may determine a battery cell, which satisfies an x^{th} abnormality determination criterion (where x is a natural number that is greater than or equal to 1), as an x^{th} abnormal battery cell. The processor 220 may determine whether an accumulated time of a first battery cell, an accumulated time of a fifth battery cell, and an accumulated time of an n^{th} battery cell deviate from the overall average value 600 by the certain range or more and satisfy the upper limit criterion 610 or the lower limit criterion 620. Accordingly, the accumulated time of the first battery cell, the accumulated time of the fifth battery cell, and the accumulated time of the n^{th} battery cell may be less than or equal to the third abnormality determination criterion 63, may exceed the fourth abnormality determination criterion 64, and may be included within the certain range based on the overall average value 600. In this case, the processor 220 may determine the first battery cell, the fifth battery cell, and the n^{th} battery cell as normal battery cells with no abnormality.

For example, the accumulated time of the second battery cell may exceed the first abnormality determination criterion 61, and thus the processor 220 may determine the second battery cell as a first abnormal battery cell.

For example, the accumulated time of the third battery cell may exceed the second abnormality determination criterion 62, and thus the processor 220 may determine the third battery cell as a second abnormal battery cell.

For example, the accumulated time of the fourth battery cell may exceed the fourth abnormality determination criterion 64, and thus the processor 220 may determine the fourth battery cell as a fourth abnormal battery cell.

For example, an accumulated time of a sixth battery cell may exceed the third abnormality determination criterion 63, and thus the processor 220 may determine the sixth battery cell as a third abnormal battery cell.

In some embodiments, in the case of the second battery cell, the accumulated time of the second battery cell may satisfy the first abnormality determination criterion 61 having the largest standard deviation value and thus may also satisfy the second abnormality determination criterion 62 and the third abnormality determination criterion 63. However, in this case, the processor 220 may determine that only the first abnormality determination criterion 61 having the largest standard deviation value is satisfied, thereby determining the second battery cell as the first abnormal battery cell.

As an additional example, the processor 220 may provide a notification based on a result of identifying an abnormal battery cell. For example, the processor 220 may provide one of a notification, a battery charge limit command, and a battery use stop command based on the identifying the abnormal battery cell.

In some examples, the processor 220 may provide a notification, which corresponds to a degree of abnormality of the abnormal battery cell, to a user. In some embodiments, the processor 220 may provide a command to stop use of the battery (e.g., a battery use stop command) when the degree of abnormality of the abnormal battery cell is the greatest or is above a maximum notification threshold), may provide an alert or a notification when the degree is the smallest or below a minimum notification threshold, and may provide a command to limit the charge of the battery (e.g., a battery charge limit command) when the degree is intermediate or below the maximum notification threshold and above the minimum notification threshold. In this regard, the processor 220 may transmit the battery use stop command or the battery charge limit command to a device (for example, a vehicle, a ship, an aircraft, or the like), in which a battery is used, according to the degree of abnormality of the abnormal battery cell, or an alert or simple notification to a user or the device in which the battery is used. For example, the processor 220 may determine that a larger defect is present in an abnormal battery cell as a degree of abnormality becomes greater and may provide a corresponding notification.

In some embodiments, in the case of an abnormal battery cell that satisfies the upper limit criterion 610, the processor 220 may determine that a degree of abnormality is greater as a standard deviation of an abnormality determination criterion becomes greater. That is, the processor 220 may determine that a degree of abnormality of the first abnormal battery cell satisfying the first abnormality determination criterion 61 is greater than a degree of abnormality of the second abnormal battery cell satisfying the second abnormality determination criterion 62. This also applies to battery cells that satisfy the lower limit criterion 620, and thus redundant descriptions are omitted.

For example, when the identified abnormal battery cell is the first abnormal battery cell, the processor 220 may provide the battery use stop notification. In some embodiments, when the identified abnormal battery cell is the second abnormal battery cell, the processor 220 may provide the battery charge limit notification. In some embodiments, when the identified abnormal battery cell is the third battery cell or the fourth battery cell, the processor 220 may provide the simple notification. In some embodiments, the simple notification may refer to a notification provided to a device in which a battery pack is used or a company that has manufactured the battery pack.

Through the method described in the present disclosure, it is possible to identify an abnormal battery cell among a one or more of battery cells included in a battery pack.

In some embodiments, a notification may be provided according to a identified abnormal battery cell, thereby securing user safety.

Meanwhile, the above-described method may be recorded as a program that may be executed on a computer and may be implemented in a general-purpose digital computer operating the program using a computer-readable recording medium. In addition, the structure of the data used in the method described above may be recorded on a computer-readable recording medium through various means. Examples of the computer-readable recording medium include storage media such as magnetic storage media (for example, ROMs, RAMs, floppy disks, hard disks, and the like), and optical read media (for example, CD-ROMs and digital videodisks (DVDs)).

According to an embodiment of the present disclosure, a balancing operation of battery cells may be used for diagnosing safety of a battery pack.

In addition, a balancing operation of each battery cell may be recorded and monitored to grasp whether the deterioration of a specific battery cell is accelerated, thereby determining whether to use the battery.

In addition, when an abnormality has occurred in a battery, a battery use stop notification, a charge limit notification, or the like may be provided for user safety.

However, the effects that may be achieved through the present disclosure are not limited to the above-described effects, and other technical effects that are not described herein will be clearly understood by those skilled in the art from the following descriptions of the present disclosure.

It will be understood by those skilled in the art to which the present embodiment pertains that the present disclosure may be implemented in modified forms without departing from the spirit and scope of the present disclosure. Therefore, the disclosed methods should be considered in an illustrative aspect rather than a restrictive aspect. The scope of the present disclosure should be defined by the claims rather than the above-mentioned description, and equivalents to the claims should be interpreted to fall within the present disclosure.

What is claimed is:

1. A method for identifying an abnormal battery cell of a battery, the method comprising:
performing a balancing operation based on a voltage difference between a plurality of battery cells;
measuring times spent to perform the balancing operation and accumulating the times for respective ones of the battery cells for generating an accumulated time for the respective ones of the battery cells; and
identifying at least one abnormal battery cell satisfying an abnormality determination criterion among the plurality of battery cells based on the accumulated times.

2. The method of claim 1, wherein the performing of the balancing operation is based on determining that the voltage difference between the plurality of battery cells is greater than or equal to a preset value.

3. The method of claim 2, wherein the performing comprises:
identifying a balancing battery cell on which the balancing operation is to be performed among the plurality of battery cells based on determining that the voltage difference is greater than or equal to the preset value; and
performing the balancing operation on the balancing battery cell.

4. The method of claim 1, wherein the accumulating comprises accumulating individual times spent to perform the balancing operation on each of the plurality of battery cells.

5. The method of claim 1, wherein the identifying comprises:
calculating the abnormality determination criterion for the plurality of battery cells based on he accumulated times; and
identifying the at least one abnormal battery cell among the plurality of battery cells based on the abnormality determination criterion.

6. The method of claim 5, wherein the abnormality determination criterion comprises at least one upper limit criterion or at least one lower limit criterion,
the upper limit criterion is satisfied based on the at least one abnormal battery cell having a first accumulated time that exceeds the upper limit criterion, and
the lower limit criterion is satisfied based on the at least one abnormal battery cell having a second accumulated time that is below the lower limit criterion.

7. The method of claim 5, wherein the calculating of the abnormality determination criterion comprises:
calculating an average value of the accumulated times for the respective ones of the battery cells based on a sum of the accumulated times for the respective ones of the battery cells; and
calculating the abnormality determination criterion based on the average value.

8. The method of claim 1, further comprising: providing a notification based on identifying the at least one abnormal battery cell.

9. The method of claim 8, wherein the providing comprises providing one of an alert, a first command to limit charge of the battery, or a second command to stop use of the battery.

10. A computer-readable recording medium having recorded thereon a program for causing a computer to execute the method of claim 1.

11. An apparatus for identifying an abnormal battery cell of a battery, the apparatus comprising:
a processor; and
a memory, wherein the memory stores instructions that, when executed by the processor, cause the processor to:
perform a balancing operation based on a voltage difference between a plurality of battery cells;
measure times spent to perform the balancing operation and accumulate the times for respective ones of the battery cells for generating an accumulated time for the respective ones of the battery cells; and
identify at least one abnormal battery cell satisfying an abnormality determination criterion among the plurality of battery cells based on the accumulated times.

12. The apparatus of claim 11, wherein the instructions that cause the processor to perform the balancing operation include instructions that cause the processor to perform the balancing operation based on determining that the voltage difference between the plurality of battery cells is greater than or equal to a preset value.

13. The apparatus of claim 12, wherein the instructions further cause the processor to:
identify a balancing battery cell on which the balancing operation is to be performed among the plurality of battery cells based on determining that the voltage difference is greater than or equal to the preset value; and
perform the balancing operation on the balancing battery cell.

14. The apparatus of claim 11, wherein instructions that cause the processor to accumulate the time include instructions that cause the processor to accumulate individual times spent to perform the balancing operation on each of the plurality of battery cells.

15. The apparatus of claim 11, wherein the instructions that cause the processor to identify include instructions that cause the processor to:
calculate the abnormality determination criterion for the plurality of battery cells based on the accumulated times; and
identify the at least one abnormal battery cell among the plurality of battery cells based on the abnormality determination criterion.

16. The apparatus of claim 15, wherein the abnormality determination criterion comprises at least one upper limit criterion or at least one lower limit criterion,
the upper limit criterion is configured to be satisfied based on the at least one abnormal battery cell having a first accumulated time that exceeds the upper limit criterion, and
the lower limit criterion is configured to be satisfied based on the at least one abnormal battery cell having a second accumulated time that is below the lower limit criterion.

17. The apparatus of claim 15, wherein the instructions that cause the processor to calculate the abnormality determination criterion include instructions that cause the processor to:
calculate an average value of the accumulated times for the respective ones of the battery cells based on a sum of the accumulated times for the respective ones of the battery cells; and
calculate the abnormality determination criterion based on the average value.

18. The apparatus of claim 11, wherein the at least one processor is further configured to provide a notification based on a result of identifying the at least one abnormal battery cell.

19. The apparatus of claim 18, wherein the notification comprises one of a simple notification, a battery charge limit command, and a battery use stop command.
